(19) United States
(12) Patent Application Publication
(10) Pub. No.: US 2025/0380546 A1
(43) Pub. Date: Dec. 11, 2025

(54) LIGHT-EMITTING DEVICE

(71) Applicant: KYOCERA CORPORATION, Kyoto-shi, Kyoto (JP)

(72) Inventor: Shin YAMADA, Kyoto-shi, Kyoto (JP)

(21) Appl. No.: 18/878,553

(22) PCT Filed: Jun. 5, 2023
(86) PCT No.: PCT/JP2023/020876

§ 371 Date: Dec. 23, 2024

(30) Foreign Application Priority Data
Jun. 29, 2022 (JP) 2022-104600

(51) Int. Cl. H10H 29/34

(52) U.S. Cl. CPC H10H 29/34

(57) ABSTRACT

A light-emitting device includes a body and a plurality of light-emitting areas on the body. Each of the plurality of light-emitting areas includes a plurality of light emitters. The plurality of light-emitting areas includes a first light-emitting area and a second light-emitting area. The second light-emitting area includes, at least in a portion of the second light-emitting area, a high-density portion including light emitters of the plurality of light emitters at a higher number density than the first light-emitting area. The high-density portion includes light-emitting units each including a first light emitter and a second light emitter. In each of the light-emitting units, one of the first light emitter or the second light emitter emits light. The first light emitter or the second light emitter selectively emits light as determined regularly or irregularly for each of the light-emitting units or determined regularly and irregularly across the light-emitting units.

### TECHNICAL FIELD

The present disclosure relates to a light-emitting device including light emitters such as micro-light-emitting diodes (micro-LEDs).

### BACKGROUND OF INVENTION

A light-emitting device with a known technique is described in, for example, Patent Literature 1. A light-emitting device with another known technique is described in, for example, Patent Literature 2.

### CITATION LIST

### Patent Literature

Patent Literature 1: Japanese Unexamined Patent Application Publication (Translation of PCT Application) No. 2022-523081
Patent Literature 2: WO 2011/077885

### SUMMARY

In the light-emitting devices with the known techniques described in Patent Literatures 1 and 2 described above, numerous microscopic light emitters such as micro-LEDs transferred onto a target substrate can cause variation in luminance and color (wavelength) on the substrate, and thus reduce display quality. Light-emitting devices with less variation in luminance and color and with higher display quality are thus awaited.

In one or more aspects of the present disclosure, a light-emitting device includes a body and a plurality of light-emitting areas on the body. Each of the plurality of light-emitting areas includes a plurality of light emitters. The plurality of light-emitting areas includes a first light-emitting area and a second light-emitting area. The second light-emitting area includes, at least in a portion of the second light-emitting area, a high-density portion including light emitters of the plurality of light emitters at a higher number density than the first light-emitting area. The high-density portion includes light-emitting units each including a first light emitter and a second light emitter. In each of the light-emitting units, one of the first light emitter or the second light emitter emits light. The first light emitter or the second light emitter selectively emits light as determined regularly or irregularly for each of the light-emitting units or determined regularly and irregularly across the light-emitting units.

### BRIEF DESCRIPTION OF THE DRAWINGS

The objects, features, and advantages of the present disclosure will be more apparent from the following detailed description and the drawings.

FIG. 1A is a schematic plan view of a light-emitting device according to one embodiment of the present disclosure.

FIG. 1B is a schematic plan view of a light-emitting device according to another embodiment of the present disclosure.

FIG. 1C is a schematic plan view of a light-emitting device according to another embodiment of the present disclosure.

FIG. 2 is a schematic plan view of a light-emitting device according to another embodiment of the present disclosure.

FIG. 3 is a plan view of a light-emitting device with multiple light emitters aligned in a line (row).

FIG. 4 is a schematic plan view of a light emitter wafer.

FIG. 5 is an enlarged plan view of portion IV in FIG. 4.

FIG. 6 is a photograph showing light emission from a display panel prepared for examining unevenness in emission characteristics.

FIG. 7 is a schematic plan view of a light emitter wafer for examining uneven luminance in the light emitter wafer, with a portion of the wafer enlarged in a plan view.

FIG. 8 is a schematic plan view of a light emitter wafer for examining uneven color in the light emitter wafer, with a portion of the wafer enlarged in a plan view.

FIG. 9 is a schematic plan view of a light emitter wafer for examining uneven luminance in the light emitter wafer.

FIG. 10 is a schematic plan view of a light emitter wafer for examining uneven luminance in the light emitter wafer.

FIG. 11 is a plan view of a substrate including transfer areas on which multiple light emitters are transferred from a light emitter wafer with a stamp, without the orientation of the light emitters being changed.

FIG. 12 is a schematic plan view of multiple light emitters being mounted.

FIG. 13A is an enlarged photograph showing the distribution of the luminance of many light emitters mounted through a non-rotational mounting process, with boundary lines appearing between mounted areas (between areas treated with a stamp).

FIG. 13B is an enlarged photograph showing the distribution of the luminance of many light emitters mounted by rotating the stamp or, in other words, through a rotational mounting process.

FIG. 14 is a graph showing luminance distributions between detection positions A-A′ in FIGS. 13A and 13B.

FIG. 15A is an enlarged photograph showing the distribution of wavelengths (colors), with boundary lines appearing between mounted areas.

FIG. 15B is an enlarged photograph showing the distribution of the wavelengths of many light emitters mounted through the rotational mounting process.

FIG. 16 is a graph showing wavelength distributions between detection positions B-B′in FIGS. 15A and 15B.

FIG. 17 is a partial plan view of an example light-emitting device 1 according to an embodiment of the present disclosure.

FIG. 18 is a sectional view taken along section line C1-C2 in FIG. 17.

FIG. 19A is a diagram describing the procedure for mounting light emitters onto the entire area.

FIG. 19B is a diagram describing the procedure for mounting light emitters onto the entire area.

FIG. 19C is a diagram describing the procedure for mounting light emitters onto the entire area.

FIG. 20A is a diagram describing the procedure for mounting light emitters onto luminance adjustment areas (high-density portions).

FIG. 20B is a diagram describing the procedure for mounting light emitters onto luminance adjustment areas (high-density portions).

FIG. 20C is a diagram describing the procedure for mounting light emitters onto luminance adjustment areas (high-density portions).

### DESCRIPTION OF EMBODIMENTS

With a known technique described in Patent Literature 1, light emitters are transferred with a first transfer stamp from a wafer or a carrier substrate to an intermediate carrier at a first density and are transferred with a second transfer stamp from the intermediate carrier to a target substrate at a second density that is one n-th (n is an integer) the first density. In this manner, an array area common to all three colors is formed on the target substrate.

A light-emitting device with a known technique described in Patent Literature 2 includes multiple solid light emitters distributed on a body and a control circuit for controlling the level of a current to be supplied to the solid light emitters. The body includes multiple areas having different solid light emitter distribution densities. The control circuit performs control to supply a larger current to the solid light emitters in an area with a lower distribution density than to the solid light emitters in an area with a higher distribution density.

One or more embodiments of the present disclosure will now be described with reference to the drawings. In the embodiments of the present disclosure, the light-emitting device may include known components that are not illustrated, for example, circuit boards, wiring conductors, and control ICs (L26I). In the figures, the same reference numerals denote substantially corresponding components. Such components will not be described repeatedly or will be described briefly.

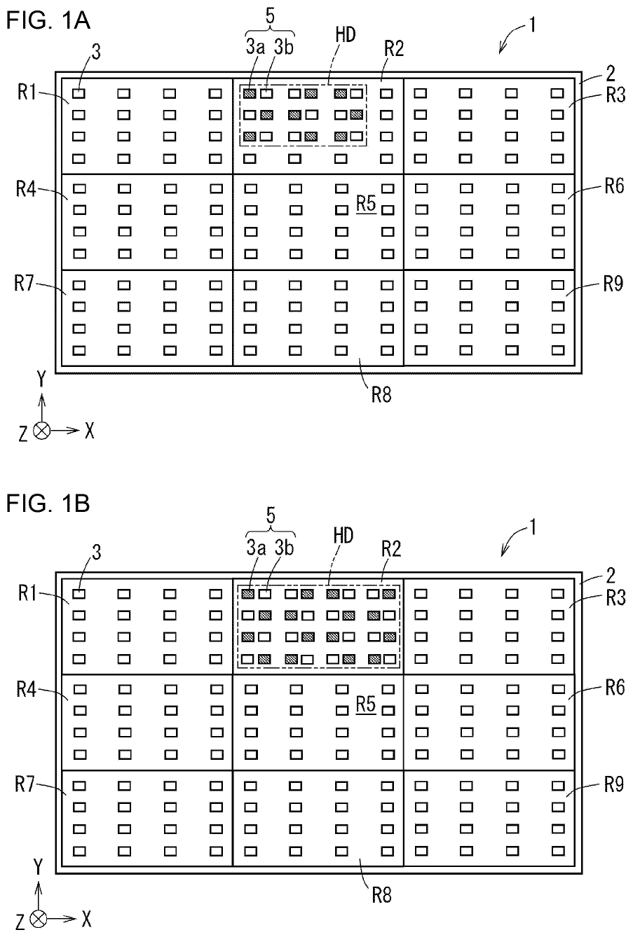

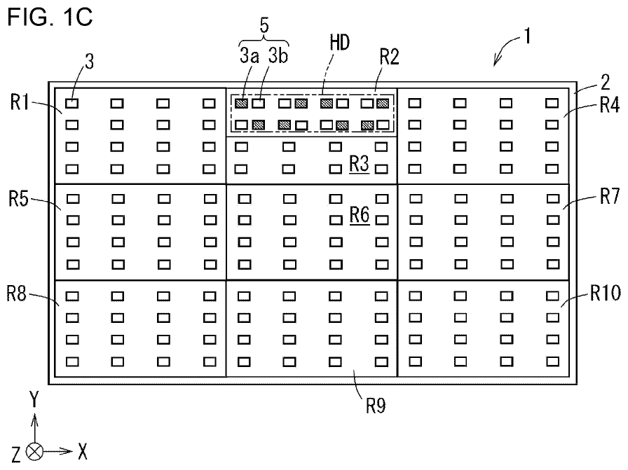

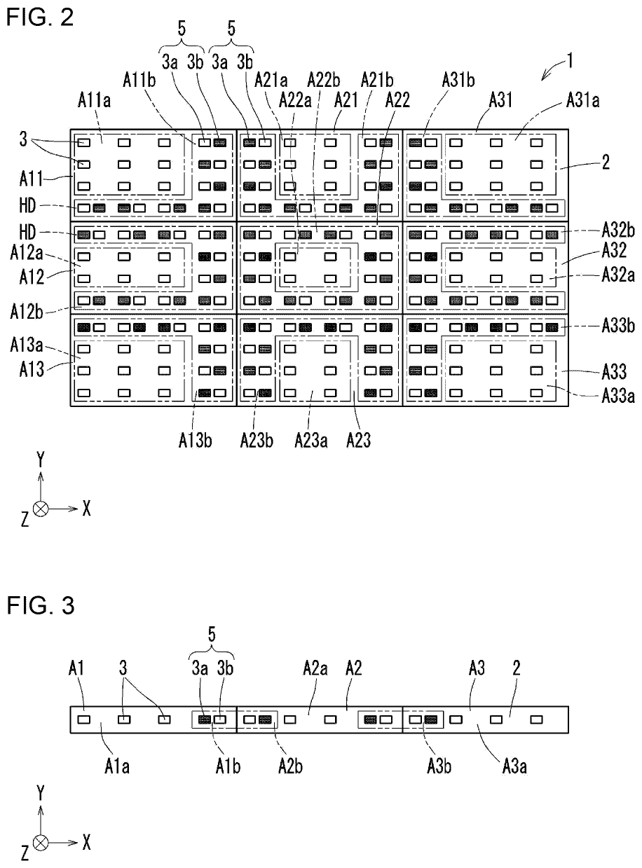

FIGS. 1A, 1B, 1C, and 2 are schematic plan views of light-emitting devices 1 according to various embodiments of the present disclosure. FIG. 3 is a plan view of a light-emitting device 1 including multiple light emitters aligned in a line (row). Note that, in FIGS. 1A to 3, light emitters 3 emitting no light are colored in gray for ease of understanding. An orthogonal coordinate system with three axes X, Y, and Z is used for ease of explanation.

In the present embodiment, the light-emitting device 1 illustrated in each of FIGS. 1A, 1B, and 1C includes a body 2 and multiple light-emitting areas R1 to R9 (R1 to R10 in FIG. 1C) on the body 2. Each of the multiple light-emitting areas includes multiple light emitters 3. The multiple light-emitting areas R1 to R9 include a first light-emitting area R1 and a second light-emitting area R2. The second light-emitting area R2 includes, at least in a portion of the second light-emitting area R2, a high-density portion HD including light emitters 3 of the multiple light emitters 3 at a higher number density than the first light-emitting area R1. The high-density portion HD includes light-emitting units 5. Each of the light-emitting units 5 includes a first light emitter 3a and a second light emitter 3b. In each of the light-emitting units 5, one of the first light emitter 3a or the second light emitter 3b emits light. The first light emitter 3a or the second light emitter 3b selectively emits light as determined regularly or irregularly for each of the light-emitting units 5 or determined regularly and irregularly across the light-emitting units 5.

The light-emitting device I with the above structure produces the effects described below: For example, the multiple light emitters 3 included in the first light-emitting area R1 have emission characteristics (e.g., luminance or wavelengths) with a gradient distribution (also referred to as a first gradient distribution), and the multiple light emitters 3 included in the second light-emitting area R2 have emission characteristics (e.g., luminance or wavelengths) with a gradient distribution (also referred to as a second gradient distribution). When the first gradient distribution and the second gradient distribution are compared, the second gradient distribution may have a larger gradient. In this case, uneven luminance or other unevenness caused by the second gradient distribution can be reduced. The structure can also reduce a noticeable boundary portion between the first light-emitting area R1 and the second light-emitting area R2 caused by a gap (difference) in the emission characteristics. In other words, one of the first light emitter 3a or the second light emitter 3b included in each of the light-emitting units 5 in the high-density portion HD may have the second gradient distribution that is the same as or similar to the first gradient distribution and has a greater gradient than the first gradient distribution. In this case, when the other of the first light emitter 3a or the second light emitter 3b has a distribution different from the first gradient distribution, uneven luminance or other unevenness caused by the second gradient distribution can be reduced.

The ratio of the high-density portion HD in the second light-emitting area R2, or the number of light emitters 3 in the high-density portion HD to the total number of light emitters 3 in the second light-emitting area R2, may be in a range of, but is not limited to, 1 to 100%, 5 to 50%, or 10 to 30%. Note that, a range of values referred to now and hereafter as one value to another value intends to mean the two values being inclusive. When the second gradient distribution has a still greater gradient than the first gradient distribution, the high-density portion HD may have a still larger ratio in the second light-emitting area R2. This structure can further reduce, for example, uneven luminance caused by the second gradient distribution. When the ratio of the gradient of the second gradient distribution to the gradient of the first gradient distribution (the gradient of the second gradient distribution/the gradient of the first gradient distribution) is 1.1 to 1.5, for example, the ratio of the high-density portion HD may be about 10 to 30%. When (the gradient of the second gradient distribution/the gradient of the first gradient distribution) is 1.5 to 2, the ratio of the high-density portion HD may be about 30 to 50%. When (the gradient of the second gradient distribution/the gradient of the first gradient distribution) is 2 or greater, the ratio of the high-density portion HD may be about 50 to 100%.

As illustrated in FIG. 1A, the light-emitting device 1 may include the high-density portion HD in a portion of the second light-emitting area R2. In this structure, when the light emitters 3 (one of a set of first light emitters 3a or a set of second light emitters 3b) included in the portion of the second light-emitting area R2 have an emission characteristic with the second gradient distribution, or in other words, when the second light-emitting area R2 locally includes a portion with the second gradient distribution, uneven luminance or other unevenness caused by the second gradient distribution can be reduced. The structure can also reduce a noticeable boundary portion between the first light-emitting area R1 and the second light-emitting area R2 caused by a gap in the emission characteristics.

As illustrated in the light-emitting device 1 in FIG. 1B, the full portion of the second light-emitting area R2 may be the high-density portion HD. When the full portion of the second light-emitting area R2 has the second gradient distribution, uneven luminance or other unevenness caused by the second gradient distribution can be reduced. The structure can also reduce a noticeable boundary portion between the first light-emitting area R1 and the second light-emitting area R2 caused by a gap in the emission characteristics.

As illustrated in FIG. 1C, the light-emitting device I may include the second light-emitting area R2 and the first light-emitting area R1 having different sizes (areas). The second light-emitting area R2 may be, for example, smaller than the first light-emitting area R1. In this structure, the size of the second light-emitting area R2 is adjustable based on the size of a portion having the second gradient distribution. This can minimize the number of first light emitters 3a and the number of second light emitters 3b included in the high-density portion HD.

In each of the light-emitting units 5, one of the first light emitter 3a or the second light emitter 3b emits light. The first light emitter 3a or the second light emitter 3b selectively emits light as determined regularly or irregularly for each of the light-emitting units 5 or determined regularly and irregularly across the light-emitting units 5. When the first light emitter 3a or the second light emitter 3b selectively emits light as determined regularly, the light emitter emitting light in one of the light-emitting units 5 may be different from the light emitter emitting light in an adjacent light-emitting unit 5 as illustrated in FIGS. 1A to IC. This structure can further reduce, for example, uneven luminance caused by the second gradient distribution. This can also further reduce a noticeable boundary portion between the first light-emitting area R1 and the second light-emitting area R2 caused by a gap in the emission characteristics. The first light emitter 3a or the second light emitter 3b selectively emits light as determined for every other multiple light-emitting units. For example, the first light emitter 3a in each of multiple light-emitting units 5 adjacent to one another (a set of light-emitting units 5) may emit light, and the second light emitter 3b in each of a subsequent set of light-emitting units 5 may emit light. The number of light-emitting units 5 included in one set may be, but is not limited to, about 2 to 5.

The light-emitting device 1 may include a drive, and the drive may include a change controller. The change controller selectively changes, between the first light emitter 3a and the second light emitter 3b, the light emitter that emits light regularly or irregularly for each of the light-emitting unit 5. The drive may be on the body 2 or on a surface (also referred to as a light-emitting surface) of the body 2 including the multiple light-emitting areas R1 to R9. The drive may be on a surface different from the light-emitting surface of the body 2, or for example, on a surface opposite to the light emitting surface. The drive may be a drive element such as an IC or an LSI circuit or may be a circuit board or a flexible printed circuit (FPC) on which the drive element and a circuit element are mounted. The change controller may be program software stored in a storage such as a RAM or a ROM. When the first light emitter 3a or the second light emitter 3b selectively emits light as determined irregularly for each of the light-emitting units 5, the change controller may include irregularity generating means such as pseudorandom number generation program software.

In each of the light-emitting units 5, one of the first light emitter 3a or the second light emitter 3b emits light. The first light emitter 3a or the second light emitter 3b selectively emits light as determined regularly or irregularly for each of the light-emitting units 5 or determined regularly and irregularly across the light-emitting units 5. The high-density portion HD may include both the light-emitting unit 5 in which the first light emitter 3a or the second light emitter 3b selectively emits light as determined regularly and the light-emitting unit 5 in which the first light emitter 3a or the second light emitter 3b selectively emits light as determined irregularly. The light-emitting units 5 in which the first light emitter 3a or the second light emitter 3b selectively emits light as determined irregularly may outnumber the light-emitting units 5 in which the first light emitter 3a or the second light emitter 3b selectively emits light as determined regularly. This structure produces the effects described below: When one of a set of first light emitters 3a or a set of second light emitters 3b included in the light-emitting units 5 in the high-density portion HD has the second gradient distribution that is the same as or similar to the first gradient distribution and has a greater gradient than the first gradient distribution, and the other of the set of first light emitters 3a or the set of second light emitters 3b has a distribution different from the first gradient distribution, the structure can reduce, for example, uneven luminance caused by the second gradient distribution.

When one of a set of first light emitters 3a or a set of second light emitters 3b included in the light-emitting units 5 in the high-density portion HD has the second distribution that is the same as or similar to the first gradient distribution and has a greater gradient than the first gradient distribution, and the other of the set of first light emitters 3a or the set of second light emitters 3b has a distribution different from the first gradient distribution, the structure may be as described below: For the gradient of the second gradient distribution being still greater than the first gradient distribution, the other of the set of first light emitters 3a or the set of second light emitters 3b (the set having a distribution different from the first gradient distribution) may include more light emitters emitting light than the one of the set of first light emitters 3a or the set of the second light emitters 3b (the set having the second gradient distribution). This structure can further reduce, for example, uneven luminance caused by the second gradient distribution. For example, when (the gradient of the second gradient distribution/the gradient of the first gradient distribution) is 1.1 to 1.5, the number of light emitters emitting light in the other of the set of first light emitters 3a or the set of second light emitters 3b may be about 1.1 to 1.5 times the number of light emitters emitting light in the one of the set of first light emitters 3a or the set of second light emitters 3b. When (the gradient of the second gradient distribution/the gradient of the first gradient distribution) is 1.5 to 2, the number of light emitters emitting light in the other of the set of first light emitters 3a or the set of second light emitters 3b is about 1.5 to 2 times the number of light emitters emitting light in the one of the set of first light emitters 3a or the set of second light emitters 3b. When (the gradient of the second gradient distribution/the gradient of the first gradient distribution) is 2 or greater, the number of light emitters emitting light in the other of the set of first light emitters 3a or the set of second light emitters 3b is about 2 or more times the number of light emitters emitting light in the one of the set of first light emitters 3a or the set of second light emitters 3b.

When one of a set of first light emitters 3a or a set of second light emitters 3b included in the light-emitting units 5 in the high-density portion HD has the second distribution that is the same as or similar to the first gradient distribution and has a greater gradient than the first gradient distribution, and the other of the set of first light emitters 3a or the set of second light emitters 3b has a distribution different from the first gradient distribution, the structure may be as described below. In each of the light-emitting units 5, one of the first light emitter 3a or the second light emitter 3b emits light. The first light emitter 3a or the second light emitter 3b selectively emits light as determined regularly and irregularly across the light-emitting units 5. In this structure, for the second gradient distribution having a still greater gradient than the first gradient distribution, the light-emitting units 5 in which the first light emitter 3a or the second light emitter 3b selectively emits light as determined irregularly may outnumber the light-emitting units 5 in which the first light emitter 3a or the second light emitter 3b selectively emits light as determined regularly. This structure can further reduce, for example, uneven luminance caused by the second gradient distribution. For example, when (the gradient of the second gradient distribution/the gradient of the first gradient distribution) is 1.1 to 1.5, the number of light-emitting units 5 in which the first light emitter 3a or the second light emitter 3b selectively emits light as determined irregularly may be about 1.1 to 1.5 times the number of light-emitting units 5 in which the first light emitter 3a or the second light emitter 3b selectively emits light as determined regularly. When (the gradient of the second gradient distribution/the gradient of the first gradient distribution) is 1.5 to 2, the number of light-emitting units 5 in which the first light emitter 3a or the second light emitter 3b selectively emits light as determined irregularly may be about 1.5 to 2 times the number of light-emitting units 5 in which the first light emitter 3a or the second light emitter 3b selectively emits light as determined regularly. When (the gradient of the second gradient distribution/the gradient of the first gradient distribution) is 2 or greater, the number of light-emitting units 5 in which the first light emitter 3a or the second light emitter 3b selectively emits light as determined irregularly may be about 2 or more times the number of light-emitting units 5 in which the first light emitter 3a or the second light emitter 3b selectively emits light as determined regularly.

The light emitter emitting light may be changed between the first light emitter 3a and the second light emitter 3b for each frame. For the frame frequency of 60 Hz, for example, the light emitter emitting light may be changed 60 times per second. This can further reduce, for example, uneven luminance caused by the second gradient distribution. This can also further reduce a noticeable boundary portion between the first light-emitting area R1 and the second light-emitting area R2 caused by a gap in the emission characteristics. The light emitter emitting light may be changed in every multiple frames. The number of multiple frames may be, but is not limited to, about 2 to 10.

The high-density portion HD may be included in one or more of the third light-emitting area R3 to the tenth light-emitting area R10. When at least one of the third light-emitting area R3 to the tenth light-emitting area R10 has the second gradient distribution, for example, the light-emitting area having the second gradient distribution may include the high-density portion HD.

A single light-emitting unit 5 may include three or more light emitters 3. For example, the single light-emitting unit 5 may include a third light emitter. In this structure, one of the first light emitter 3a, the second light emitter 3b, or the third light emitter may emit light, and the first light emitter 3a, the second light emitter 3b, or the third light emitter may selectively emit light as determined regularly or irregularly for each of the light-emitting units 5. Any two of the first light emitter 3a, the second light emitter 3b, or the third light emitter may emit light, and the two of the first light emitter 3a, the second light emitter 3b, or the third light emitter may selectively emit light as determined regularly or irregularly for each of the light-emitting units 5. These structures can further reduce, for example, uneven luminance caused by the second gradient distribution. These structures can also further reduce a noticeable boundary portion between adjacent light-emitting areas caused by a gap in the emission characteristics.

As illustrated in FIG. 2, the light-emitting device 1 may include multiple light-emitting areas A11, A12, A13, A21, A22, A23, A31, A32, and A33. The first light-emitting area A11 and the second light-emitting area A21 may be adjacent to each other. The high-density portion HD may be located in a boundary portion between the first light-emitting area A11 and the second light-emitting area A21. The high-density portion HD is located, in the first light-emitting area A11, in a boundary portion adjacent to the second light-emitting area A21 and, in the second light-emitting area A21, in a boundary portion adjacent to the first light-emitting area A11. This structure can further reduce a noticeable boundary portion between the first light-emitting area A11 and the second light-emitting area A21 caused by a gap in the emission characteristics.

Note that, in FIG. 2, the high-density portion HD in the first light-emitting area A11 is illustrated as a high-density portion A11b, and the high-density portion HD in the second light-emitting area A21 is illustrated as a high-density portion A21b. A normal-density portion other than the high-density portion HD in the first light-emitting area A11 is illustrated as a normal-density portion A11a. The second light-emitting area A21, the third light-emitting area A31, the fourth light-emitting area A12, the fifth light-emitting area A22, the sixth light-emitting area A32, the seventh light-emitting area A13, the eighth light-emitting area A23, and the ninth light-emitting area A33 include normal-density portions illustrated as normal-density portions A21a, A31a, A12a, A22a, A32a, A13a, A23a, and A33a. Note that the first light-emitting area A11 to the ninth light-emitting area A33 are hereafter also collectively referred to as light-emitting areas A11 to A33.

At least one of the third light-emitting area A13 to the ninth light-emitting area A33 may include the high-density portion HD. As illustrated in FIG. 2, the first light-emitting area A11 to the ninth light-emitting area A33 may each include the high-density portion HD. The third light-emitting area A13 to the ninth light-emitting area A33 include the high-density portions HD illustrated as the high-density portions A31b, A12b, A22b, A32b, A13b, A23b, and A33b.

The high-density portions A11b to A33b each include multiple light-emitting units 5. Each of the multiple light-emitting units 5 includes a single first light emitter 3a and a single second light emitter 3b. The first light emitter 3a and the second light emitter 3b may be collectively referred to as light emitters 3 without the lower-case letters a and b. In each of the multiple light-emitting units 5, one of the first light emitter 3a or the second light emitter 3b alone is turned on, and the other light emitter is not turned on. The one of the light emitter 3a or 3b being turned on is set regularly or irregularly in the high-density portions A11b to A33b.

In each of the first light-emitting area A11 and the second light-emitting area A21 in the light-emitting device 1 in FIG. 2, the multiple light emitters 3 in a portion (normal-density portion A11a or A12a) other than the high-density portion A11b or A12b may have an emission characteristic with a gradient distribution. The multiple first light emitters 3a may have an emission characteristic with a first distribution. The second light emitters 3b may have an emission characteristic with a second distribution. One of the first distribution or the second distribution may be the gradient distribution described above, and the other of the first distribution or the second distribution may be different from the gradient distribution described above. The light emitter emitting light, of the first light emitter 3a and the second light emitter 3b, in a light-emitting unit 5 may be different from the light emitter emitting light, of the first light emitter 3a and the second light emitter 3b, in an adjacent light-emitting unit 5. This structure can reduce a noticeable boundary portion between the first light-emitting area A11 and the second light-emitting area A21 caused by a gap in the gradient distributions when the multiple light emitters 3 included in the first light-emitting area A11 have the gradient distribution that is the same as or similar to the gradient distribution of the multiple light emitters 3 included in the second light-emitting area A21.

A single light-emitting unit 5 may include three or more light emitters 3. For example, the single light-emitting unit 5 may include a third light emitter. In this structure, one of the first light emitter 3a, the second light emitter 3b, or the third light emitter may emit light, and the first light emitter 3a, the second light emitter 3b, or the third light emitter may selectively emit light as determined regularly or irregularly for each of the light-emitting units 5. Any two of the first light emitter 3a, the second light emitter 3b, or the third light emitter may emit light, and the two of the first light emitter 3a, the second light emitter 3b, or the third light emitter may selectively emit light as determined regularly or irregularly for each of the light-emitting units 5. These structures can further reduce a noticeable boundary portion between adjacent light-emitting areas caused by a gap in the emission characteristics.

The body 2 of the light-emitting device 1 may be, for example, a plate, a flexible film, or any one of solid shapes such as a block and a sphere. The body 2 includes a flat surface, a composite surface including multiple flat surfaces, a curved surface, or a complex surface on which the multiple light emitters 3 are mountable. The body 2 may be, for example, a display surface of a display device, a cylinder such as a utility pole, a surface of a building, or an inner or outer surface of a vehicle such as a train. For the body 2 being a plate, the plate may be, for example, triangular, quadrangular, trapezoidal, polygonal with five or more sides, circular, or oval in a plan view.

The body 2 may be made of a glass material, a ceramic material, or a resin material. Examples of the glass material include borosilicate glass, crystallized glass, and quartz. Examples of the ceramic material include alumina (A1₂O₃), zirconia (ZrO₂), silicon nitride (Si₃N₄), silicon carbide (SiC), and aluminum nitride (AlN). Examples of the resin material include an epoxy resin, a polyimide resin, a polyamide resin, an acrylic resin, and a polycarbonate resin. The body 2 may be made of, for example, a metal material, an alloy material, or a semiconductor material. Examples of the metal material include aluminum (A1), magnesium (Mg) (specifically, high-purity magnesium with a Mg content of 99.95% or higher), zinc (Zn), tin (Sn), copper (Cu), chromium (Cr), and nickel (Ni). Examples of the alloy material include duralumin, which is an aluminum alloy mainly containing aluminum (an A1—Cu alloy, an A1—Cu—Mg alloy, an A1—Zn alloy, or a Mg—Cu alloy), a magnesium alloy containing magnesium as a main component (a Mg—A1 alloy, a Mg—Zn alloy, or a Mg—A1—Zn alloy), titanium boride, stainless steel, and a Cu—Zn alloy. Examples of the semiconductor material include silicon (Si), germanium (Ge), gallium arsenide (GaAs), and gallium nitride (GaN). The body 2 may be a composite body being a stack of different types of bodies.

FIG. 3 is a plan view of a light-emitting device with multiple light emitters 3 aligned in a line (row). The light-emitting device with this structure is used as, for example, a light source of a three-dimensional printing device (3D print head) on which the multiple light emitters 3 are aligned linearly (one-dimensionally). The technique in one or more embodiments of the present disclosure may also be used in a light-emitting device with this structure. In FIG. 3, a first light-emitting area is indicated by the reference numeral A1, a second light-emitting area is indicated by the reference numeral A2, and a third light-emitting area is indicated by the reference numeral A3. Normal-density portions in the first light-emitting area A1 to the third light-emitting area A3 are illustrated as normal-density portions A1a, A2a, and A3a. High-density portions HD in the first light-emitting area A1 to the third light-emitting area A3 are illustrated as high-density portions A1b, A2b, and A3b.

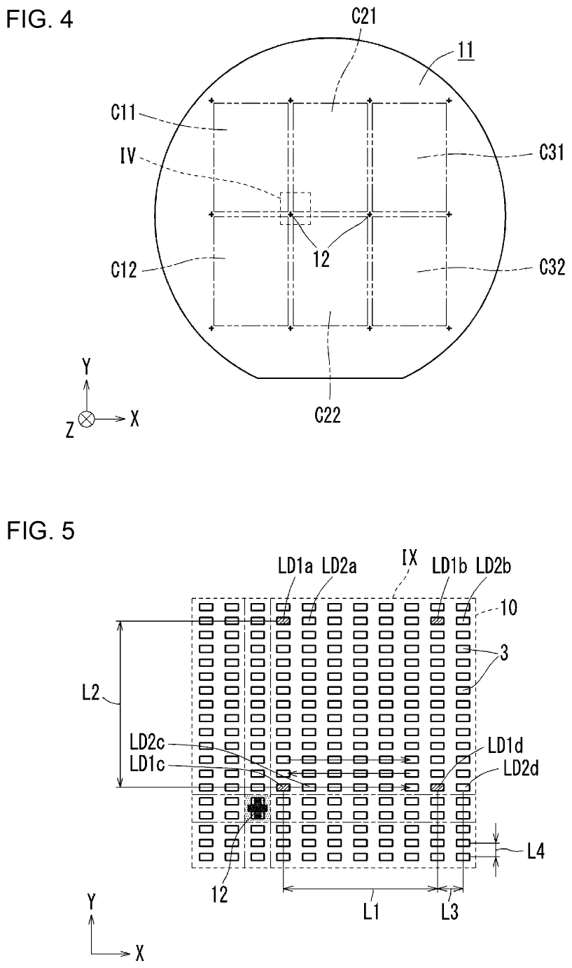

FIG. 4 is a schematic plan view of a light emitter wafer 11. FIG. 5 is an enlarged plan view of portion IV in FIG. 4. The single light emitter wafer 11 includes several millions of light emitters 3. Six transfer areas C11, C12, C21, C22, C31, and C32 each include four corners with positioning marks 12. A stamp has a stamp pitch LI in a first direction X and a stamp pitch L2 in a second direction Y. The light emitters 3 have an emitter pitch L3 in the first direction X and an emitter pitch L4 in the second direction Y. The multiple light emitters 3 can be detached from the light emitter wafer 11 by each of the transfer areas C11 to C32 in the same direction and can be transferred to a light-emitting substrate 10.

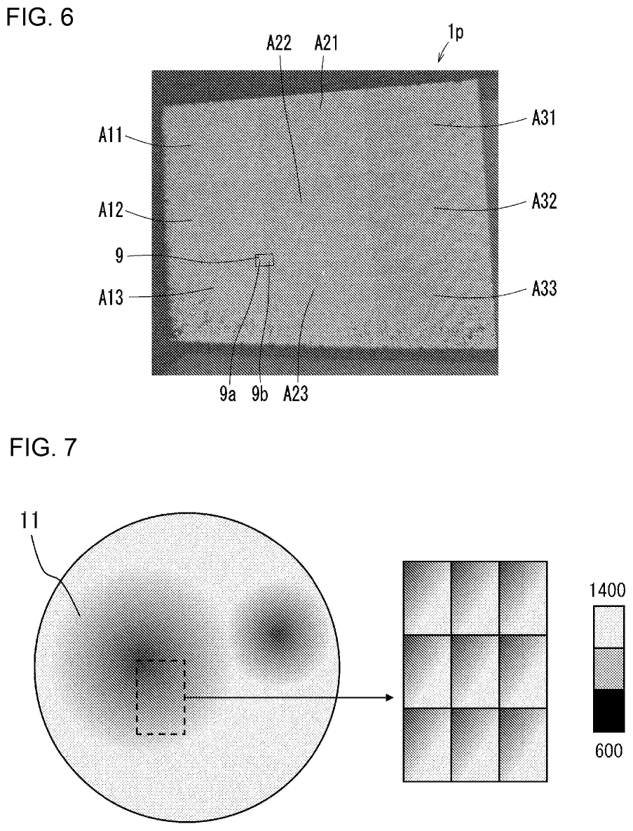

In the second transfer area C21, for example, the multiple light emitters 3 are detached in the first direction X as described below. For simplicity, four first light emitters 3a (LD1a, LD1b, LD1c, and LD1d) are transferred to the first transfer area C11, and four second light emitters 3b (LD2a, LD2b, LD2c, and LD2d) are transferred to the second transfer area C21. In other words, the four second light emitters 3b (LD2a, LD2b, LD2c, and LD2d) are at positions displaced from the four first light emitters 3a (LD1a, LD1b, LD1c, and LD1d) by the size of a single light emitter 3 in the first direction X (in a positive X-direction, or to the right in FIG. 4). In this case, the distribution of the emission characteristic of the four first light emitters 3a (LD1a, LD1b, LD1c, and LD1d) is substantially the same as the distribution of the emission characteristic of the four second light emitters 3b (LD2a, LD2b, LD2c, and LD2d) as illustrated in FIGS. 6 and 7. When the four first light emitters 3a (LD1a, LD1b, LD1c, and LD1d) detached from the light emitter wafer 11 are placed onto the first transfer area C11 on the body 2 without changing the arrangement at the detachment and the four second light emitters 3b (LD2a, LD2b, LD2c, and LD2d) detached from the light emitter wafer 11 are placed on the second transfer area C21 of the body 2 without changing the arrangement at the detachment, the specific distributions of the emission characteristics and the boundary portion between adjacent areas are more viewable.

In one embodiment of the present disclosure, the light-emitting device 1 includes, on the second transfer area C21 on the body 2, the multiple second light emitters 3b (LD2a, LD2b, LD2c, and LD2d) that are detached from the light emitter wafer 11 in a direction (e.g., the second direction Y) different from one direction (e.g., the first direction X) and mounted on the second transfer area C21 without changing the arrangement at the detachment. In one embodiment of the present disclosure, the light-emitting device 1 includes, on the second transfer area C21 on the body 2, the multiple second light emitters 3b (LD2a, LD2b, LD2c, and LD2d) with the second transfer area C21 being in an orientation rotated by a predetermined rotation angle with respect to the first transfer area C11. In these structures, the distribution of the emission characteristic of the transferred four first light emitters 3a (LD1a, LD1b, LD1c, and LD1d) is different from the distribution of the emission characteristic of the transferred four second light emitters 3b (LD2a, LD2b, LD2c, and LD2d) in one direction (e.g., the first direction X). Thus, the specific distributions of the emission characteristics are less viewable, and the boundary portion between adjacent areas is also less viewable.

FIG. 6 is a photograph showing light emission from a display panel 1p prepared for examining unevenness in emission characteristics. To examine unevenness in the emission characteristics of the multiple light emitters 3, the inventor prepared the display panel 1p including the light emitters 3 mounted in the same patterns. Note that the light-emitting device 1 is prepared by installing attachments such as a frame, a housing, an operation button, and an external input terminal to the display panel 1p. With all the light emitters 3 on the display panel 1p emitting light, the light-emitting areas A11 to A33 (corresponding to the transfer area C11 to C33) in a matrix of three rows and three columns were visually distinguished. In other words, the boundary lines between the adjacent light-emitting areas A11 to A33 were viewable. The viewable boundary lines appear when the multiple light emitters 3 included in each of the transfer area C11 to C33 have the same distribution of emission wavelengths (colors) or, in other words, are transferred from the semiconductor wafer using the same patterns. This reduces the display quality of the light-emitting device 1. When an area 9 on the boundary line between the light-emitting area A13 (transfer area C13) and the light-emitting area A23 (transfer area C23) adjacent to each other was examined, subareas 9a and 9b on both sides of the boundary line (vertical boundary line) in the area 9 had a wavelength difference of 4 nm. The area 9 thus had uneven color. Such a slight wavelength difference is visually perceived as a boundary line by a viewer and thus reduces the display quality. In one or more embodiments of the present disclosure, the light-emitting device 1 solves such issues of the known technique.

Note that the first transfer area C11 to the ninth transfer area C33 are hereafter also collectively referred to as transfer areas C11 to C33.

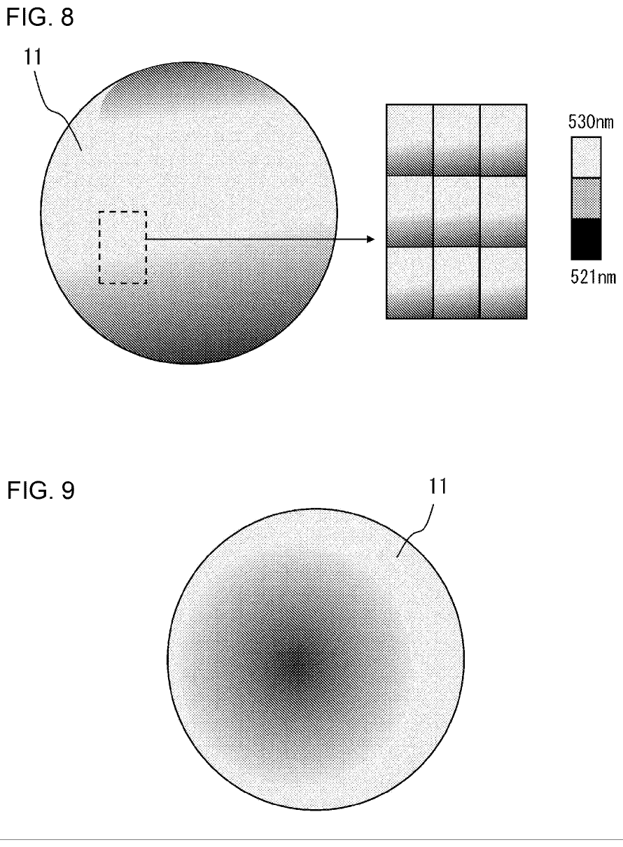

FIG. 7 is a schematic plan view of the light emitter wafer 11 for examining uneven luminance in the light emitter wafer 11, with its portion enlarged in a plan view. FIG. 8 is a schematic plan view of the light emitter wafer 11 for examining uneven color in the light emitter wafer 11, with its portion enlarged in a plan view. The light emitter wafer 11 includes light emitters 3 formed on its surface. When the light emitters to be transferred were turned on, uneven luminance and uneven color (wavelengths) were observed as illustrated in FIGS. 7 and 8. When the light emitters 3 with such uneven luminance and uneven color are mounted on the light-emitting substrate 10, the boundary lines between the transfer areas C11 to C33 are perceivable as described above, which reduces display quality.

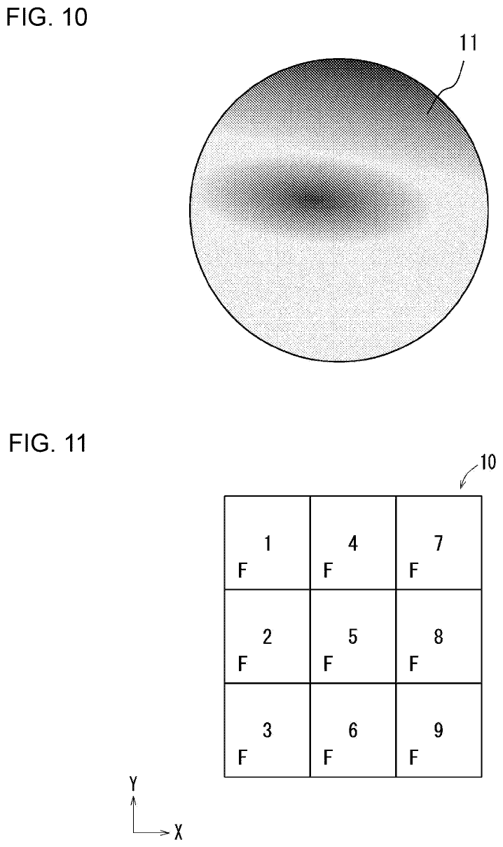

FIG. 9 is a schematic plan view of the light emitter wafer 11 for examining uneven luminance. FIG. 10 is a schematic plan view of the light emitter wafer 11 for examining uneven color. When excitation light was applied to the light emitters 3 on the light emitter wafer 11, the light emitters 3 emitted light with uneven luminance as illustrated in FIG. 9. When a drive voltage was applied to the light emitters 3 on the light emitter wafer 11, the light emitters emitted light with uneven wavelengths (colors) as illustrated in FIG. 10. When the multiple light emitters 3 on areas indicated by the reference numerals F are picked up with a stamp ST from such a light emitter wafer 11 and transferred to the light-emitting substrate 10 without the orientation being changed, the multiple transferred light emitters 3 also cause uneven luminance and uneven wavelengths.

Such uneven luminance and uneven color (wavelengths) may appear as described below: For example, when a p-n junction being a GaAs active layer sandwiched between GaAlAs cladding layers is formed on a GaAs wafer substrate by vapor deposition such as metalorganic chemical vapor deposition (MOCVD), the amounts of ingredients in the active layer and the cladding layers are (unevenly) distributed in the wafer substrate surface. This causes the unevenness.

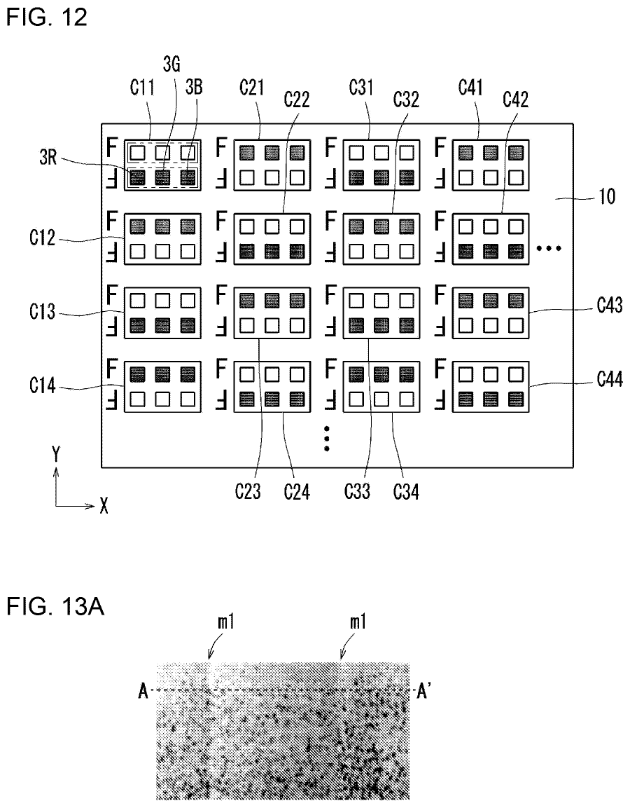

FIG. 11 is a plan view of the light-emitting substrate 10 including the transfer areas on which many light emitters 3 are transferred from the light emitter wafer 11 with the stamp ST, without the orientation of the light emitters 3 being changed. FIG. 12 is a schematic plan view of the light-emitting substrate 10 on which many light emitters 3 are mounted. The light-emitting substrate 10 in FIG. 12 is prepared by repeating a process of directly mounting many light emitters 3 picked up with the stamp ST (a mounting process without rotating the stamp ST by 180°, also referred to as a non-rotational mounting process) and a process of mounting many light emitters 3 picked up with the stamp ST after rotating the stamp ST by 180° (also referred to as a rotational mounting process). For example, in FIG. 12, the multiple light emitters 3 indicated by the reference numerals F are mounted through the non-rotational mounting process, and the multiple light emitters 3 indicated by the inverted reference numerals F are mounted through the rotational mounting process.

A single pixel includes three light emitters 3 (red, green, and blue light emitters 3) indicated by the reference numeral F and three light emitters (red, green, and blue light emitters 3) indicated by the inverted reference numeral F. In this manner, the single pixel is the light-emitting unit 5 in the high-density portion HD. One of a set of the three light emitters 3 indicated by the reference numeral F or a set of the three light emitters 3 indicated by the inverted reference numeral F is turned on, and the other set is not turned on. The emitting set of the light emitters 3 in a pixel may differ from the emitting set of the light emitters 3 in an adjacent pixel.

When a light emitter 3R emits red light, a light emitter 3G emits green light, and a light emitter 3B emits blue light, the multiple transfer areas C11, C12, C13, C14, C21, C22, C23, C24, C31, C32, C33, C34, C41, C42, C43, and C44 each have a regular structure including the light emitters 3R, 3G, and 3B indicated by the reference numeral F and the 180°-inverted light emitters 3R, 3G, and 3B indicated by the inverted reference numeral F. For each of red, green, and blue colors in the first transfer areas C11 to C44, a redundant circuit controls one of the two light emitters 3 to emit light and the other of the two light emitters 3 not to emit light.

FIG. 13A is an enlarged photograph showing the distribution of the luminance of many light emitters 3 mounted through the non-rotational mounting process, with boundary lines appearing between mounted areas (between the areas treated with the stamp ST). FIG. 13B is an enlarged photograph showing the distribution of the luminance of many light emitters 3 mounted by rotating the stamp ST or, in other words, through the rotational mounting process. When many light emitters 3 are mounted on each of the mounted areas in the same orientation without the stamp ST being rotated, the boundary lines appear clearly as indicated by the reference numeral m1 in FIG. 13A. However, as in FIG. 12, when the half of the light emitters 3 are rotated by 180° with the stamp ST before mounting, the boundary lines are hardly identifiable as indicated by the reference numeral m2 in FIG. 13B.

The effects described above are produced by the structure described below. In other words, the light emitters 3 in a first area (light emitters 3 indicated by the reference numeral F) and the light emitters 3 in a second area (light emitters 3 indicated by the inverted reference numeral F) have different distributions of the emission characteristics. The difference is caused by the light emitters 3 mounted on the second area through the rotational mounting process. In this structure, a single mounted area includes a mixture of many light emitters 3 having different distributions of the emission characteristics.

FIG. 14 is a graph showing the luminance distribution between detection positions A-A′ in FIGS. 13A and 13B. The circular marks in FIG. 14 represent the luminance in FIG. 13B for rotational mounting, and the triangular marks in FIG. 14 represent the luminance in FIG. 13A for mounting in the same orientation. For the light emitters 3 mounted through the rotational mounting, the maximum luminance difference is 3%. In contrast, for the light emitters 3 mounted in the same orientation, the maximum luminance difference is 17%, which is larger.

To measure the luminance and the wavelength of the light emitters 3, a measurer that can measure the luminance and the wavelengths of individual chips may be used. The measurer may be, for example, a spectroradiometer SR-5000 (Topcon). Such a measurer can measure the luminance and the wavelengths of all the light emitters 3 mounted on the light-emitting substrate 10.

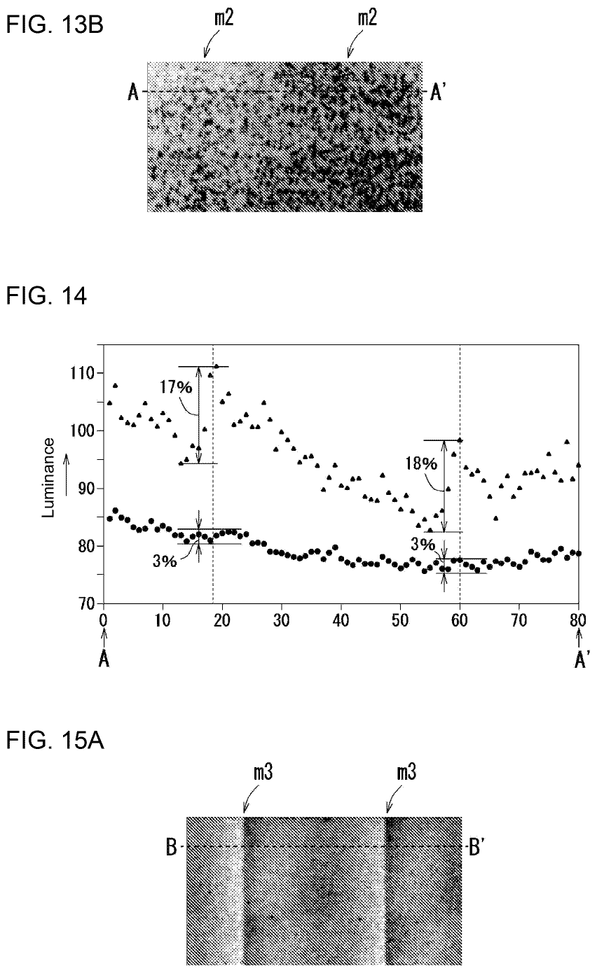

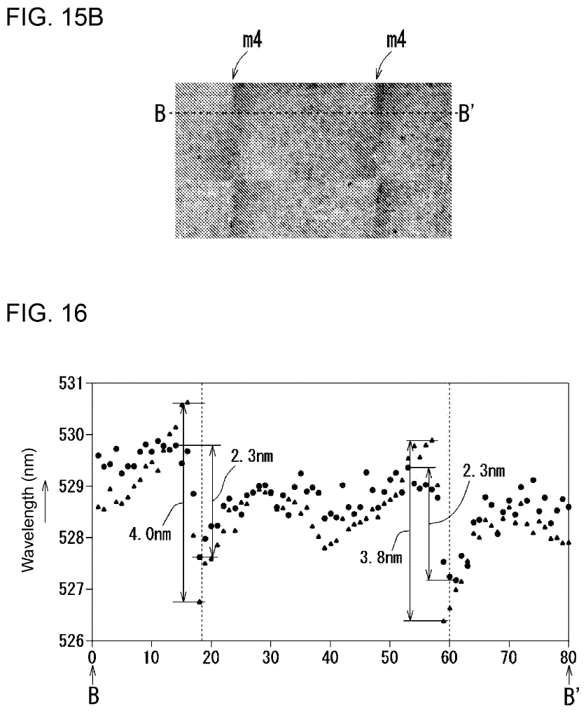

FIG. 15A is an enlarged photograph showing the distribution of wavelengths (colors), with boundary lines appearing between mounted areas. FIG. 15B is an enlarged photograph showing the distribution of the wavelengths of many light emitters 3 mounted through the rotational mounting process. When many light emitters 3 are mounted through the non-rotational mounting process, clear boundary lines appear as indicated by the reference numerals m3 in FIG. 15A. In contrast, for transfer areas on which the half of the light emitters 3 are transferred and mounted without the stamp ST being rotated and the remaining light emitters 3 are transferred and mounted with the stamp ST being rotated by 180°, the boundary lines appear less clearly as indicated by the reference numeral m4 in FIG. 15B.

FIG. 16 is a graph showing the wavelength distributions in FIGS. 15A and 15B between detection positions B-B′. The circular marks in FIG. 16 represent the wavelength in FIG. 15B for rotational mounting, and the triangular marks in FIG. 16 represent the wavelength in FIG. 15A for mounting in the same orientation. For the light emitters 3 mounted through rotational mounting, the maximum wavelength difference is 2.3 nm. In contrast, for the light emitters 3 mounted in the same orientation, the maximum wavelength difference is 4.0 nm, which is larger.

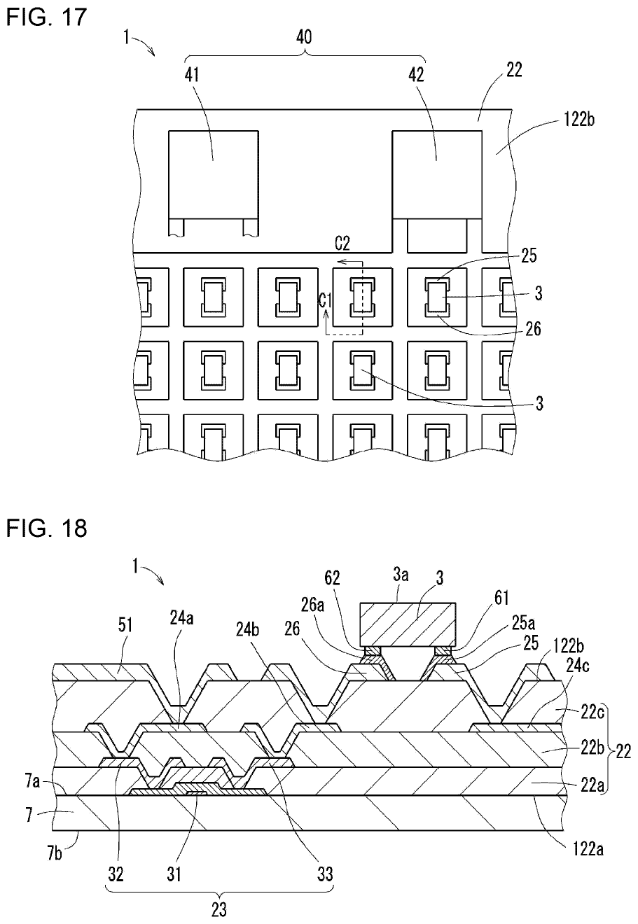

FIG. 17 is a partial plan view of an example light-emitting device 1 according to an embodiment of the present disclosure. FIG. 18 is a sectional view taken along section line C1-C2 in FIG. 17. In the present embodiment described below, drive transistors are n-channel thin-film transistors (TFTs). The drive transistors may be p-channel TFTs.

In the present embodiment, the light-emitting device 1 includes an insulating body 22, drive transistors 23, a power terminal 40, anode electrode wires 25, cathode electrode wires 26, and the light emitters 3.

The insulating body 22 includes a first surface 122a and a second surface 122b. The second surface 122b is the other main surface opposite to the first surface 122a. The insulating body 22 may be, for example, triangular, quadrangular including square or rectangular, trapezoidal, hexagonal, circular, or oval, or may have any other shape. The insulating body 22 may be a single insulating layer, or may be a stack of multiple insulating lavers.

In the present embodiment, the insulating body 22 includes multiple insulating layers 22a, 22b, and 22c stacked on one another as illustrated in FIG. 18. The insulating layers 22a, 22b, and 22c may be, for example, organic insulating layers made of, for example, silicon oxide (SiO₂) or silicon nitride (Si₃N₄) or organic insulating layers made of an acrylic resin, a polyimide resin, or a polycarbonate resin. For example, the insulating layers 22a and 22b in a lower portion (closer to the substrate 7) of the insulating body 22 may be inorganic insulating layers, and the insulating layer 22c at the top of the insulating body 22 may be an organic insulating layer as a planarization layer thicker than each of the insulating layers 22a and 22b. The insulating layers 22a, 22b, and 22c may be the same or different from one another in composition, dimensions (thickness), and other features.

The insulating body 22 includes internal wires 24a to 24c. The internal wires 24a to 24c electrically connect, for example, the drive transistors 23, the power terminal 40, the anode electrode wires 25, the cathode electrode wires 26, and the light emitters 3 to one another. The internal wires 24a to 24c may be located between adjacent ones of the insulating layers 22a, 22b, and 22c. The internal wires 24a to 24c may be made of, for example, Mo/Al/Mo or MoNd/AlNd/MoNd. The stack of Mo/A1/Mo includes a Mo layer, an Al layer, and a Mo layer stacked in this order. The same or similar structure applies to other notations.

The insulating body 22 includes the anode electrode wires 25 and the cathode electrode wires 26. The anode electrode wires 25 electrically connect the internal wires 24c and anode terminals 61 of the light emitters 3. The cathode electrode wires 26 electrically connect the internal wires 24b and cathode terminals 62 of the light emitters 3. The anode electrode wires 25 and the cathode electrode wires 26 may be located on the second surface 122b or between adjacent ones of the insulating layers 22a, 22b, and 22c. The anode electrode wires 25 may be directly connected to the anode terminals 61 or may be connected to the anode terminals 61 with a transparent conductive layer 25a between the anode electrode wires 25 and the anode terminals 61. The cathode electrode wires 26 may be directly connected to the cathode terminals 62 or may be connected to the cathode terminals 62 with a transparent conductive layer 26a between the cathode electrode wires 26 and the cathode terminals 62. In the example in FIG. 17, the anode electrode wire 25 is connected to the anode terminal 61 with the transparent conductive layer 25a between the anode electrode wire 25 and the anode terminal 61. The cathode electrode wire 26 is connected to the cathode terminal 62 with the transparent conductive layer 26a between the cathode electrode wire 26 and the cathode terminal 62. The transparent conductive layers 25a and 26a may each be a transparent conductor such as tin oxide (ITO) or indium zinc oxide (IZO).

The light-emitting device I may be located on the substrate 7 as illustrated in, for example, FIG. 18. The substrate 7 includes a third surface 7a, a fourth surface 7b opposite to the third surface 7a, and a fifth surface (side surface) connecting the third surface 7a and the fourth surface 7b. The light-emitting device I may be located on the substrate 7 with the first surface 122a of the insulating body 22 facing the third surface 7a of the substrate 7.

The substrate 7 may be made of a glass material, a ceramic material, or a resin material. Examples of the glass material used for the substrate 7 include borosilicate glass, crystallized glass, and quartz. Examples of the ceramic material used for the substrate 7 include alumina (Al₂O₃), zirconia (ZrO₂), silicon nitride (Si₃N₄), silicon carbide (SiC), and aluminum nitride (AlN). Examples of the resin material used for the substrate 7 include an epoxy resin, a polyimide resin, a polyamide resin, an acrylic resin, and a polycarbonate resin.

The substrate 7 may be made of, for example, a metal material, an alloy material, or a semiconductor material. Examples of the metal material used for the substrate 7 include aluminum (A1), magnesium (Mg) (specifically, high-purity magnesium with a Mg content of 99.95% or higher), zinc (Zn), tin (Sn), copper (Cu), chromium (Cr), and nickel (Ni). Examples of the alloy material used for the substrate 7 include duralumin, which is an aluminum alloy mainly containing aluminum (an Al—Cu alloy, an Al—Cu—Mg alloy, an Al—Zn alloy, or a Mg—Cu alloy), a magnesium alloy mainly containing magnesium (a Mg-A1 alloy, a Mg—Zn alloy, or a Mg—Al—Zn alloy), titanium boride, stainless steel, and a Cu—Zn alloy. Examples of the semiconductor material used for the substrate 7 include silicon (Si), germanium (Ge), gallium arsenide (GaAs), and gallium nitride (GaN).

For the substrate 7 made of a metal material, an alloy material, or a semiconductor material, an insulating layer made of, for example, silicon oxide (SiO₂) or silicon nitride (Si₃N₄) may be located between the drive transistors 23 and the substrate 7.

Each of the drive transistors 23 is located in the insulating body 22 or on the first surface 122a of the insulating body 22. The drive transistors 23 control the light emitting operation (emission or non-emission state and the light intensity) of the light emitters 3. The drive transistors 23 may be, for example, TFTs. The drive transistors 23 may include a semiconductor film (also referred to as a channel) made of, for example, amorphous silicon (a-Si) or low-temperature polycrystalline silicon (LTPS). The drive transistors 23 may each include three terminals, or specifically, a gate electrode 31, a source electrode 32, and a drain electrode 33. The drive transistors 23 each switch conduction (on-state) and non-conduction (off-state) between the source electrode 32 and the drain electrode 33 based on the voltage applied to the gate electrode 31, and also controls a source-drain current.

In the example described below; each of the drive transistor 23 is a TFT including a semiconductor film (channel), the gate electrode 21, the source electrode 32, and the drain electrode 33. The drive transistor 23 may be an n-channel TFT or a p-channel TFT.

The power terminal 40 is connected to an external power supply that applies a power supply voltage to the power terminal 40. The power terminal 40 may be located in the insulating body 22 or on the second surface 122b of the insulating body 22, or on the third surface 7a of the substrate 7. The light-emitting device I may include multiple power terminals 40. The power terminal 40 may include one or more first power terminals 41 and one or more second power terminals 42. A first power supply voltage VDD is applied to the first power terminals 41. A second power supply voltage VSS lower than the first power supply voltage VDD is applied to the second power terminals 42. The first power supply voltage VDD and the second power supply voltage VSS are predetermined as appropriate for the type of the light emitters 3. The power terminal 40 may be made of, for example, A1, AL/Ti, Ti/Al/Ti, Mo, Mo/Al/Mo, MoNd/AlNd/MoNd, Cu, Cr, Ni, or Ag.

The power terminal 40 may not have an island-like shape, but may be an end of wiring, or an end of a feedthrough conductor such as a through-hole.

A connection conductor layer 51 connects the source electrode 32 of each of the drive transistors 23 to the power terminal 40. The connection conductor layer 51 can supply a power supply voltage to the source electrode 32 of each of the drive transistors 23. The connection conductor layer 51 may be located on the second surface 122b or between adjacent ones of the insulating layers 22a, 22b, and 22c. The connection conductor layer 51 may include a portion located on the second surface 122b and another portion located between adjacent ones of the insulating layers 22a, 22b, and 22c. The connection conductor layer 51 may be made of a transparent conductor such as ITO or IZO.

The light emitters 3 are located on the second surface 122b of the insulating body 22. Each of the light emitters 3 may be a light-emitting diode (LED) or a self-luminous light emitter such as a semiconductor laser diode (LD). The light emitters 3 are LEDs in the present embodiment, but may be micro-LEDs (μLEDs). In this case, the light emitters 3 may each be quadrangular and have each side with a length of about 1 to 100 μm inclusive or about 5 to 20 μm inclusive as viewed in a direction perpendicular to the light emitters 3 (in a direction of viewing FIG. 17 from above). When the light emitters 3 are μLEDs, the first power supply voltage VDD may be, for example, about 10 to 15 V, and the second power supply voltage VSS may be, for example, about 0 to 3 V.

The light emitters 3 each include two terminals. More specifically, the light emitters 3 include the anode terminals 61 and the cathode terminals 62. The anode terminals 61 are electrically connected to the anode electrode wires 25, and the cathode terminals 62 are electrically connected to the cathode electrode wires 26.

The light-emitting device 1 includes the multiple light emitters 3 and the multiple drive transistors 23 for driving the respective light emitters 3. The multiple light emitters 3 are arranged in a matrix on the second surface 122b.

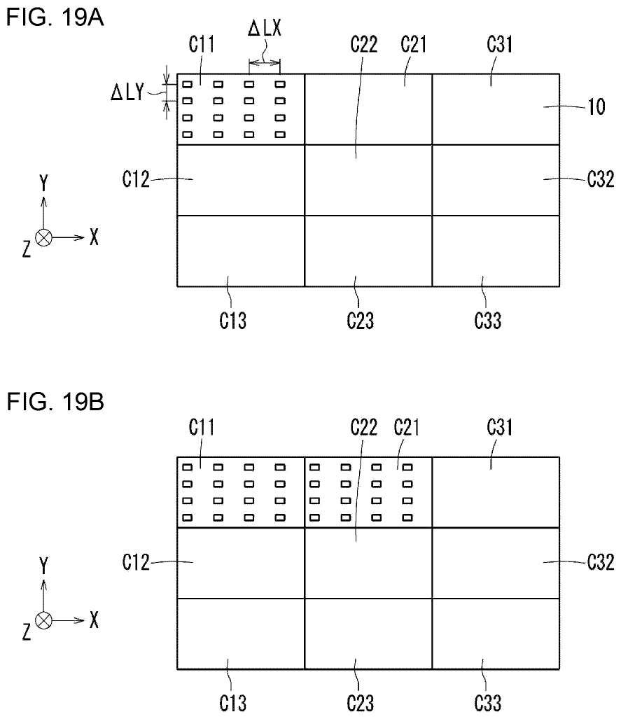

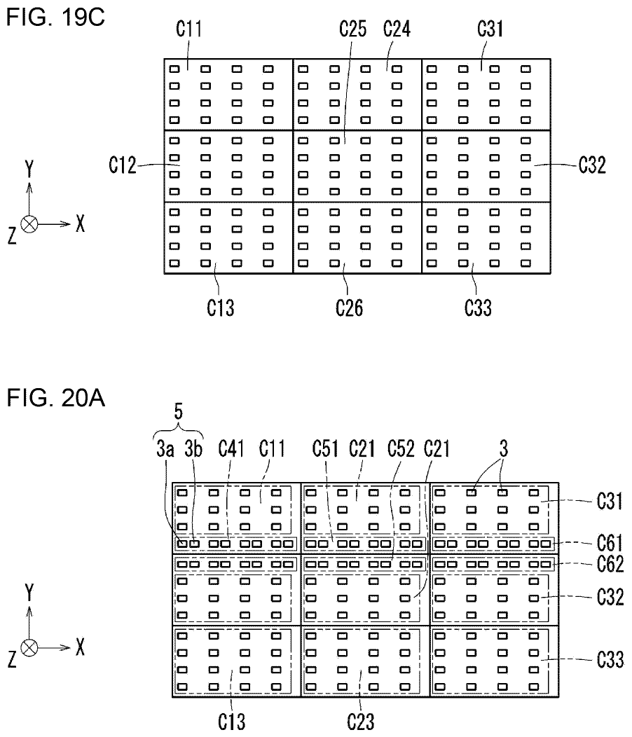

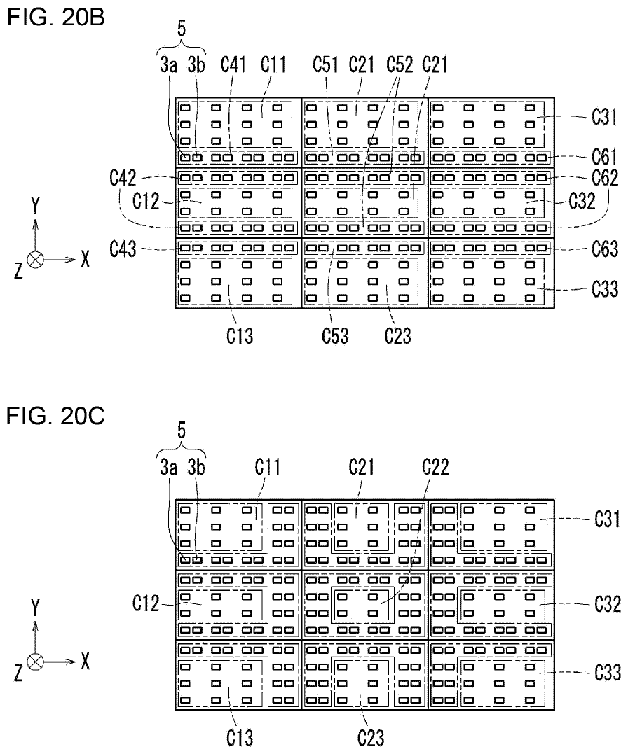

FIGS. 19A to 19C are diagrams describing the procedure for mounting the light emitters 3 on the entire area. FIGS. 20A to 20C are diagrams describing the procedure for mounting the light emitters 3 onto luminance adjustment area (high-density portions HD). FIG. 19A illustrates the arrangement of the light emitters 3 transferred on the first transfer area C11 of the light-emitting substrate 10 with a two-dimensional stamp shifted in the first direction X. The first transfer area C11 includes multiple (4×4=16 in the present embodiment) light emitters 3 aligned two-dimensionally at equal intervals of ALX in the first direction X and at equal intervals of ALY in the second direction Y.

Subsequently, the two-dimensional stamp is shifted to the second transfer area C21. As illustrated in FIG. 19B, the second transfer area C21 then includes, in the same manner as or a similar manner to the first transfer area C11, multiple light emitters 3 at equal intervals of ALX in the first direction X and at equal intervals of ALY in the second direction Y.

In the same or a similar manner, after shifting the two-dimensional stamp as many times as the number of transfer areas, the aligned light emitters 3 are transferred to all the first transfer areas C11 to C33 as illustrated in FIG. 19C.

FIGS. 20A to 20C are each a plan view of the light-emitting substrate 10 including, in the transfer areas C11 to C33, boundary transfer areas C41 to C63 serving as the high-density portions HD. This structure effectively functions when the light emitters 3 on portions (also referred to as unevenness generating portions) corresponding to the boundary transfer areas C41 to C63 have, in the transfer areas C11 to C33 for example, at least one of easily viewable luminance distribution or easily viewable color distribution (wavelength distribution). In other words, the boundary transfer areas C41 to C63 can reduce a viewable boundary portion between the transfer areas C11 to C33 caused by uneven luminance or uneven color. In each of the light-emitting units 5 in the boundary transfer areas C41 to C63, the first light emitter 3a or the second light emitter 3b selectively emits light as determined regularly or irregular for each of the light-emitting units 5.

The boundary transfer area C41 is the high-density portion HD including multiple light-emitting units 5. For example, the first light emitters 3a in the multiple light-emitting units 5 are detached in the first direction X (illustrated in FIG. 5) of a semiconductor wafer and are transferred onto the body 2 without changing the arrangement, whereas the second light emitters 3b in the multiple light-emitting units 5 are detached in the first direction X of the semiconductor wafer and are transferred onto the body 2 in an 90°-, 180°-, or 270°-rotated arrangement. Alternatively, the first light emitters 3a in the multiple light-emitting units 5 are detached in the first direction X (illustrated in FIG. 5) of a semiconductor wafer and are transferred onto the body 2 without changing the arrangement, whereas the second light emitters 3b in the multiple light-emitting units 5 are detached in a direction (e.g., the second direction Y) different from the first direction X of the semiconductor wafer and are transferred onto the body 2 without changing the arrangement. In the boundary transfer areas C42 to C63, the high-density portions HD are also formed through the same or similar operations described above. Note that the transferred light emitters 3 on the transfer areas C11 to C33 and on the boundary transfer areas C41 to C63 are spaced from one another as designed. This can reduce uneven luminance and uneven wavelengths of the light emitters 3.

In the embodiments described above, the example elements transferred to the body 2 are micro-LEDs, but elements other than micro-LEDs may be transferred to the mounting substrate. For example, the elements may be components used in electronic circuits and may be microelectromechanical systems (MEMS), semiconductor devices, or chips such as resistors and capacitors. The semiconductor devices include discrete semiconductors such as transistors, diodes, LEDs, and thyristors or integrated circuits such as ICs and LSI circuits. The LEDs include, for example, mini-LEDs. The elements may each have a thickness of 100 μm or less.

In one or more embodiments of the present disclosure, the light-emitting device is manufactured with a method including processes described below. The method includes a first process of detaching multiple first light emitters 3a from the light emitter wafer 11 (semiconductor wafer) in one direction and placing the first light emitters 3a on the first area on the light-emitting substrate 10 without changing the arrangement at the detachment, and a second process of detaching multiple second light emitters 3b from the light emitter wafer 11 in a direction different from the direction in which the first light emitters 3a are detached and placing the second light emitters 3b on the second area on the light-emitting substrate 10 without changing the arrangement at the detachment. In the second process, the multiple second light emitters 3b are arranged on the second area with the first area and the second area overlapping each other while being displaced in a predetermined direction. In this manner, as illustrated in FIGS. 1A to 3, a single first light emitter 3a and a single second light emitter 3b are included in each of the light-emitting units 5 for the high-density portion HD. In each of the light-emitting units 5, one of the first light emitter 3a or the second light emitter 3b emits light. The first light emitter 3a or the second light emitter 3b selectively emits light as determined regularly or irregularly for each of the light-emitting units 5 or determined regularly and irregularly across the light-emitting units 5.

In one or more embodiments of the present disclosure, the light-emitting device is manufactured with another method including processes described below. The method includes a first process of detaching multiple first light emitters 3a from the light emitter wafer 11 (semiconductor wafer) in one direction and placing the first light emitters 3a on the first area on the light-emitting substrate 10 without changing the arrangement at the detachment, and a second process of detaching multiple second light emitters 3b from the light emitter wafer 11 in the direction in which the first light emitters 3a are detached and placing the second light emitters 3b on the second area on the light-emitting substrate 10 without changing the arrangement at the detachment. In the second process, the multiple second light emitters 3b are placed on the second area with the second area being in an orientation rotated by a predetermined rotation angle with respect to the first area. In this manner, as illustrated in FIGS. 1A to 3, a single first light emitter 3a and a single second light emitter 3b are included in each of the light-emitting units 5 for the high-density portion HD. In each of the light-emitting units 5, one of the first light emitter 3a or the second light emitter 3b emits light. The first light emitter 3a or the second light emitter 3b selectively emits light as determined regularly or irregularly for each of the light-emitting units 5 or determined regularly and irregularly across the light-emitting units 5.

The technique according to one or more embodiments of the present disclosure may have aspects (1) to (9) described below.

### Aspect (1)

A light-emitting device, comprising:
a body: and
a plurality of light-emitting areas on the body, each of the plurality of light-emitting areas including a plurality of light emitters,
wherein the plurality of light-emitting areas includes a first light-emitting area and a second light-emitting area, the second light-emitting area includes, at least in a portion of the second light-emitting area, a high-density portion including light emitters of the plurality of light emitters at a higher number density than the first light-emitting area,
the high-density portion includes light-emitting units each including a first light emitter and a second light emitter, and
in each of the light-emitting units, one of the first light emitter or the second light emitter emits light, and the first light emitter or the second light emitter selectively emits light as determined regularly or irregularly for each of the light-emitting units or determined regularly and irregularly across the light-emitting units.

### Aspect (2)

The light-emitting device according to aspect (1), wherein
a light emitter emitting light, of the first light emitter and the second light emitter, in one light-emitting unit of the light-emitting units is different from a light emitter emitting light, of the first light emitter and the second light emitter, in a light-emitting unit adjacent to the one light-emitting unit.

### Aspect (3)

The light-emitting device according to aspect (1) or aspect (2), wherein
the first light-emitting area and the second light-emitting area are adjacent to each other, and
a full portion of the second light-emitting area is the high-density portion.

### Aspect (4)

The light-emitting device according to aspect (3), wherein
in the first light-emitting area, a plurality of light emitters included in the first light-emitting area has an emission characteristic with a gradient distribution,
in the high-density portion, a plurality of the first light emitters has an emission characteristic with a first distribution, and a plurality of the second light emitters has an emission characteristic with a second distribution,
one of the first distribution or the second distribution is a gradient distribution having a greater gradient than the gradient distribution in the first light-emitting area, and the other of the first distribution or the second distribution is a distribution different from the gradient distribution in the first light-emitting area, and
a light emitter emitting light, of the first light emitter and the second light emitter, in one light-emitting unit of the light-emitting units is different from a light emitter emitting light, of the first light emitter and the second light emitter, in a light-emitting unit adjacent to the one light-emitting unit.

### Aspect (5)

The light-emitting device according to any one of aspects (1) to (4), wherein
the emission characteristic includes at least one of luminance or an emission wavelength.

### Aspect (6)

The light-emitting device according to aspect (1), wherein
the first light-emitting area and the second light-emitting area are adjacent to each other, and
the high-density portion is located in a boundary portion between the first light-emitting area and the second light-emitting area.

### Aspect (7)

The light-emitting device according to aspect (6), wherein
a light emitter emitting light, of the first light emitter and the second light emitter, in one light-emitting unit of the light-emitting units is different from a light emitter emitting light, of the first light emitter and the second light emitter, in a light-emitting unit adjacent to the one light-emitting unit.

### Aspect (8)

The light-emitting device according to aspect (6), wherein
in each of the first light-emitting area and the second light-emitting area, light emitters of the plurality of light emitters in a portion other than the high-density portion have an emission characteristic with a gradient distribution,
a plurality of the first light emitters has an emission characteristic with a first distribution, and a plurality of the second light emitters has an emission characteristic with a second distribution,
one of the first distribution or the second distribution is the gradient distribution, and the other of the first distribution or the second distribution is a distribution different from the gradient distribution, and
a light emitter emitting light, of the first light emitter and the second light emitter, in one light-emitting unit of the light-emitting units is different from a light emitter emitting light, of the first light emitter and the second light emitter, in a light-emitting unit adjacent to the one light-emitting unit.

### Aspect (9)

The light-emitting device according to aspect (8), wherein
the emission characteristic includes at least one of luminance or an emission wavelength.

In one or more embodiments of the present disclosure, the light-emitting device can have less variation in luminance and wavelengths (colors) and have higher display quality.

Although embodiments of the present disclosure have been described in detail, the present disclosure is not limited to the embodiments described above, and may be changed or varied in various manners without departing from the spirit and scope of the present disclosure. The components described in the above embodiments may be entirely or partially combined as appropriate unless any contradiction arises.

### REFERENCE SIGNS

1 light-emitting device
2 body
3 light emitter
3a first light emitter
3b second light emitter
5 light-emitting unit
A11 to A33 first light-emitting area to ninth light-emitting area
A11a to A33a normal-density portion
A11b to A33b high-density portion
C11 to C33 first transfer area to ninth transfer area
HD high-density portion
R1 to R9 first light-emitting area to ninth light-emitting area

1. A light-emitting device, comprising:
a body; and
a plurality of light-emitting areas on the body, each of the plurality of light-emitting areas including a plurality of light emitters,
wherein the plurality of light-emitting areas includes a first light-emitting area and a second light-emitting area, the second light-emitting area includes, at least in a portion of the second light-emitting area, a high-density portion including light emitters of the plurality of light emitters at a higher number density than the first light-emitting area,
the high-density portion includes light-emitting units each including a first light emitter and a second light emitter, and
in each of the light-emitting units, one of the first light emitter or the second light emitter emits light, and the first light emitter or the second light emitter selectively emits light as determined regularly or irregularly for each of the light-emitting units or determined regularly and irregularly across the light-emitting units.

2. The light-emitting device according to claim 1, wherein
a light emitter emitting light, of the first light emitter and the second light emitter, in one light-emitting unit of the light-emitting units is different from a light emitter emitting light, of the first light emitter and the second light emitter, in a light-emitting unit adjacent to the one light-emitting unit.

3. The light-emitting device according to claim 1, wherein
the first light-emitting area and the second light-emitting area are adjacent to each other, and
a full portion of the second light-emitting area is the high-density portion.

4. The light-emitting device according to claim 3, wherein
in the first light-emitting area, a plurality of light emitters included in the first light-emitting area has an emission characteristic with a gradient distribution,
in the high-density portion, a plurality of the first light emitters has an emission characteristic with a first distribution, and a plurality of the second light emitters has an emission characteristic with a second distribution,
one of the first distribution or the second distribution is a gradient distribution having a greater gradient than the gradient distribution in the first light-emitting area, and the other of the first distribution or the second distribution is a distribution different from the gradient distribution in the first light-emitting area, and
a light emitter emitting light, of the first light emitter and the second light emitter, in one light-emitting unit of the light-emitting units is different from a light emitter emitting light, of the first light emitter and the second light emitter, in a light-emitting unit adjacent to the one light-emitting unit.

5. The light-emitting device according to claim 4, wherein
the emission characteristic includes at least one of luminance or an emission wavelength.

6. The light-emitting device according to claim 1, wherein
the first light-emitting area and the second light-emitting area are adjacent to each other, and
the high-density portion is located in a boundary portion between the first light-emitting area and the second light-emitting area.

7. The light-emitting device according to claim 6, wherein
a light emitter emitting light, of the first light emitter and the second light emitter, in one light-emitting unit of the light-emitting units is different from a light emitter emitting light, of the first light emitter and the second light emitter, in a light-emitting unit adjacent to the one light-emitting unit.

8. The light-emitting device according to claim 6, wherein
in each of the first light-emitting area and the second light-emitting area, light emitters of the plurality of light emitters in a portion other than the high-density portion have an emission characteristic with a gradient distribution,
a plurality of the first light emitters has an emission characteristic with a first distribution, and a plurality of the second light emitters has an emission characteristic with a second distribution,
one of the first distribution or the second distribution is the gradient distribution, and the other of the first distribution or the second distribution is a distribution different from the gradient distribution, and
a light emitter emitting light, of the first light emitter and the second light emitter, in one light-emitting unit of the light-emitting units is different from a light emitter emitting light, of the first light emitter and the second light emitter, in a light-emitting unit adjacent to the one light-emitting unit.

9. The light-emitting device according to claim 8, wherein
the emission characteristic includes at least one of luminance or an emission wavelength.
